(19) United States
(12) Patent Application Publication
(10) Pub. No.: US 2012/0326575 A1
(43) Pub. Date: Dec. 27, 2012

(54) DISPLAY DEVICE HOUSING

(76) Inventor: Hideyuki Hirota, Tokyo (JP)

(21) Appl. No.: 13/581,580

(22) PCT Filed: Jun. 25, 2010
(86) PCT No.: PCT/JP2010/004242

§ 371 Date: Aug. 28, 2012

(51) Int. Cl. H05K 5/03; A47B 81/06

(52) U.S. Cl. 312/7.2

(57) ABSTRACT

In a display device housing 2 in which a front panel 5 and a rear panel 8 are mounted to each other in a state in which peripheral portions 10 and 11 of the front panel 5 and the rear panel 8 are joined to each other, a rear rib protruding from the peripheral portion 11 of and being inwardly inserted into the inside of the front panel 5 is disposed on the rear panel 8. Front ribs 17 projecting from the peripheral portion 10 and being inwardly inserted into the inside of the rear panel 8 are disposed on the front panel 5. When the display device housing 2 is bent by an external force exerted thereon, the rear rib 14 and the front ribs 17 prevent the front panel 5 and the rear panel 8 from rubbing against each other.

### FIELD OF THE INVENTION

The present invention relates to a display device housing in which a front panel having an opening for screen display and a back panel are mounted to each other in such a way that their peripheral portions are joined to each other.

### BACKGROUND OF THE INVENTION

A conventional display device has a housing which consists of a pair of half-segmented housings in which their peripheral portions are joined to each other in a state in which the half-segmented housings are facing inwardly opposite to each other, and in which their engagement parts are engaged with each other and fixed in a state in which the peripheral portions are joined to each other (for example, refer to patent reference 1).

### RELATED ART DOCUMENT

### Patent Reference

Patent reference 1: Japanese Unexamined Patent Application Publication No. JP9-246772A

### SUMMARY OF THE INVENTION

In such a conventional display device housing, while a half-segmented housing on a side of the front surface of the display device resists being affected by an external force because the half-segmented housing has an opening for screen display, a half-segmented housing on a side of the rear surface of the display device is prone to be affected directly by an external force because the half-segmented housing has no opening for screen display. A problem is therefore that when an external force is exerted on the half-segmented housing on the side of the rear surface, the half-segmented housing is bent and hence the peripheral portion is moved so as to be opened outwardly, and its portion joined to the half-segmented housing on the side of the front surface rubs against this half-segmented housing and a squeak noise occurs.

The present invention is made in order to solve the above-mentioned problem, and it is therefore an object of the present invention to provide a display device housing which prevents the joint portions of a front panel and a rear panel thereof from rubbing against each other, thereby reducing the occurrence of a squeak noise.

In accordance with the present invention, there is provided a display device housing including: a front panel having a front surface in which an opening for screen display is formed, and four side surfaces; a rear panel having a rear surface and four side surfaces, the rear panel being mounted to the front panel in such a way that a peripheral portion of the four side surfaces of the rear panel is joined to a peripheral portion of the four side surfaces of the front panel in a state in which the rear and front panels are facing inwardly opposite to each other; and a rear rib protruding from a substantially entire perimeter of the peripheral portion of the rear panel, and being inwardly inserted into an inside of the front panel.

Because in the display device housing in accordance with the present invention, the rear rib protruding from the substantially entire perimeter of the peripheral portion of the rear panel is inwardly inserted into the inside of the front panel, even if an external force is exerted on the rear panel, the peripheral portion of the rear panel is not moved outwardly and hence the joint portions of the front panel and the rear panel are prevented from rubbing against each other, thereby being able to reduce the occurrence of a squeak noise.

### BRIEF DESCRIPTION OF THE FIGURES

FIG. 1 is an exploded perspective view showing an example of a display device using a display device housing in accordance with Embodiment 1 of the present invention;

FIG. 2 is an appearance perspective view showing an example of the display device using the display device housing in accordance with Embodiment 1 of the present invention;

FIG. 3 is an exploded perspective view showing the structure of the display device housing in accordance with Embodiment 1 of the present invention;

FIG. 4 is a cross-sectional view of the display device housing taken along the A-A line shown in FIG. 3, and shows a state in which a front panel 5 and a rear panel 8 are mounted to each other;

FIG. 5 is an enlarged view of a portion enclosed by a circle shown in FIG. 4;

FIG. 6 is a cross-sectional view of the display device housing taken along the B-B line shown in FIG. 4;

FIG. 7 is a cross-sectional view of the display device housing taken along the C-C line shown in FIG. 4;

FIG. 8 is a cross-sectional view of the display device housing taken along the D-D line shown in FIG. 4;

FIG. 9 is a view showing a variant of the display device housing in accordance with Embodiment 1, and is a cross-sectional view taken along a line corresponding to the A-A line shown in FIG. 3; and

FIG. 10 is a view showing a variant of the display device housing in accordance with Embodiment 1, and is an enlarged front view of each fitting member.

### EMBODIMENTS OF THE INVENTION

Hereafter, in order to explain this invention in greater detail, the preferred embodiments of the present invention will be described with reference to the accompanying drawings. Embodiment 1.

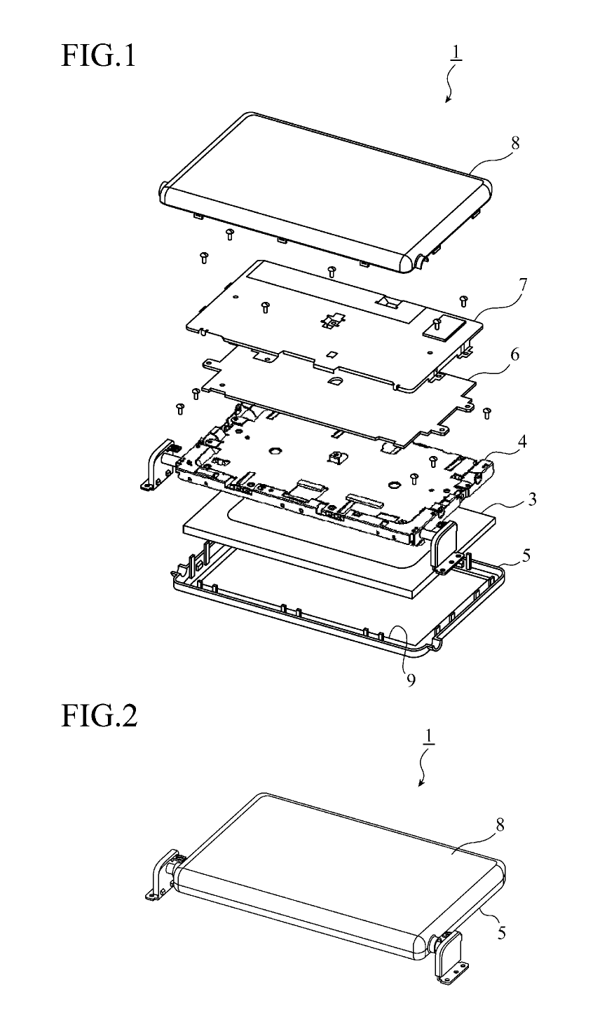

An example of a display device 1 in accordance with this Embodiment 1 is shown in FIGS. 1 and 2. Referring to an exploded perspective view of FIG. 1, a liquid crystal 3 and a holder 4 are fixed to a front panel 5 with screws, and a board 6 and a shield metal plate 7 are attached to this holder 4. A rear panel 8 is then mounted to the front panel 5 to which the liquid crystal 3, the holder 4, the board 6, and the shield metal plate 7 are attached, so that the display device 1 in such a state as shown in FIG. 2 is provided.

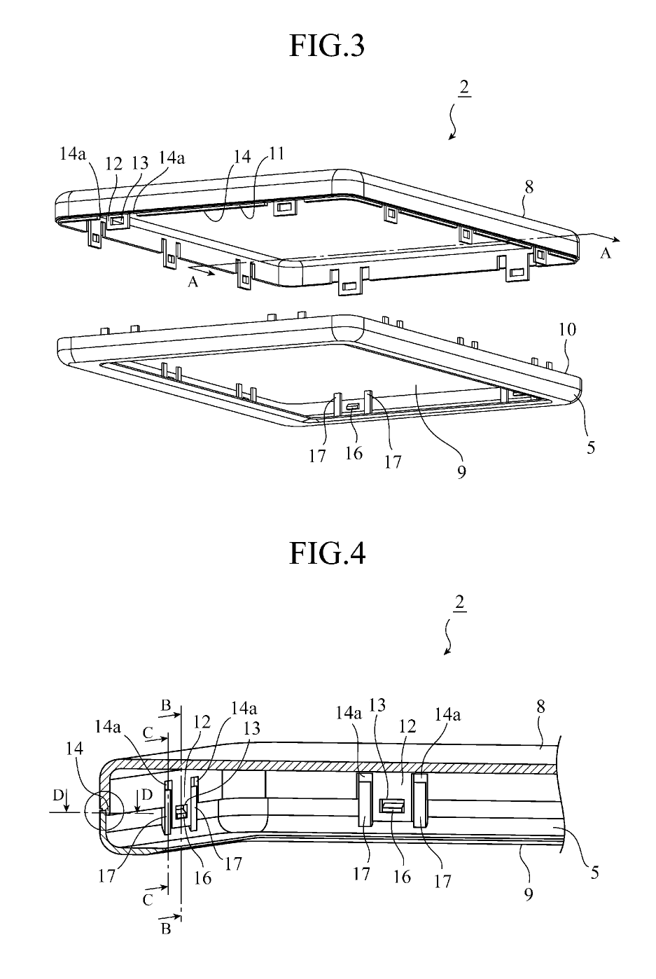

In FIG. 3, only the front panel 4 and the rear panel 8 which construct the display device housing 2 are shown with them being extracted from the display device housing. Further, FIG. 4 is a cross-sectional view, taken along the A-A line shown in FIG. 3, of the display device housing 2, and shows a state in which the front panel 5 and the rear panel 8 are mounted to each other. As shown in FIGS. 3 and 4, in the display device housing 2 in accordance with Embodiment 1, the front panel 5 having a front surface in which an opening 9 for screen display in which the liquid crystal 3 is exposed is opened and four side surfaces, and the rear panel 8 having a rear surface and four side surfaces are mounted to each other in such a way that their peripheral portions 10 and 11 are joined to each other in a state in which the front panel 5 and the rear panel 8 are facing inwardly opposite to each other.

On the rear panel 8, a rear rib 14 protruding from the peripheral portion 11 of the four side surfaces, and being inwardly inserted into the inside of the front panel 5 is disposed. Arbitrary portions of this rear rib 14 are formed as fitting protruding pieces 12, and a fitting hole 13 is opened in each of the fitting protruding pieces 12. Further, parts of the rear rib 14 on both sides of each fitting hole 13 are cut away in such a way that a pair of notches 14a are formed in the rear rib 14. Therefore, the rear rib 14 protrudes from portions of the peripheral portion 11 excluding at least the fitting protruding pieces 12 and the notches 14a. This rear rib 14 has a tapered surface 15 (not shown in FIGS. 3 and 4) facing an inner surface of the front panel 15 and being inclined in such a way that the thickness of the rear rib decreases with distance to a free end of the rear rib. The details of the tapered surface 15 will be mentioned below.

Fitting pawls 16 each of which is fitted into a fitting hole 13 are formed on the inner surface of the front panel 5. Further, pairs of front ribs 17 each protruding from the peripheral portion 10 of the front panel 5 and being inwardly inserted into the inside of the rear rib 14 via a pair of notches 14a are disposed. Each of the front ribs 17 has a tapered surface 18 (not shown in FIGS. 3 and 4) facing an inner surface of the rear panel 8 and being inclined in such a way that the thickness of the front rib decreases with distance to a free end of the front rib. The details of the tapered surface 18 will be mentioned below.

Although some of the plurality of fitting pawls 16 are not seen in the illustrated example because they are hidden by the other part of the front panel, ten fitting members each comprised of a fitting pawl 16, a fitting protruding piece 12, and a fitting hole 13 are disposed. Further, ten pairs of front ribs 17 and ten pairs of notches 14a are disposed in such a way as to be aligned with the positions of the fitting members, respectively. However, the positions and the number of the fitting members are not limited to those in this example, and an arbitrary number of fitting members can be arranged at arbitrary positions, respectively.

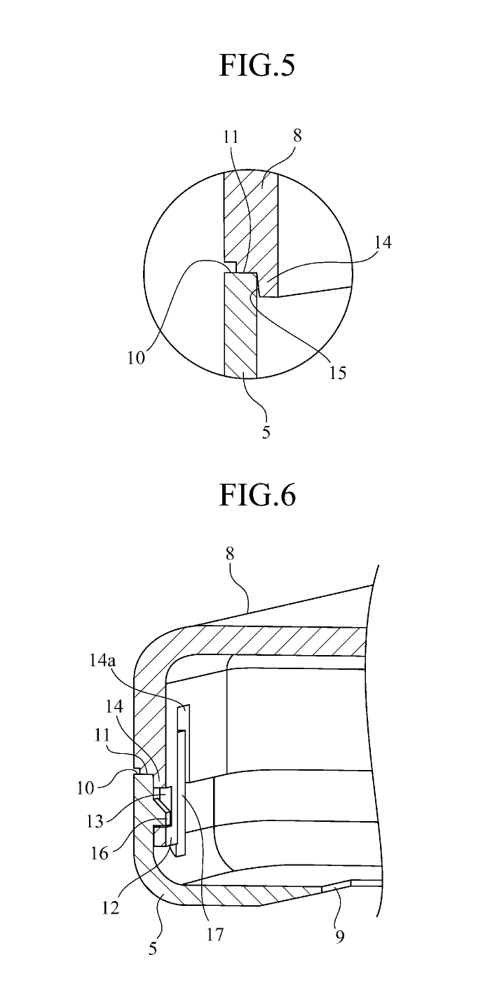

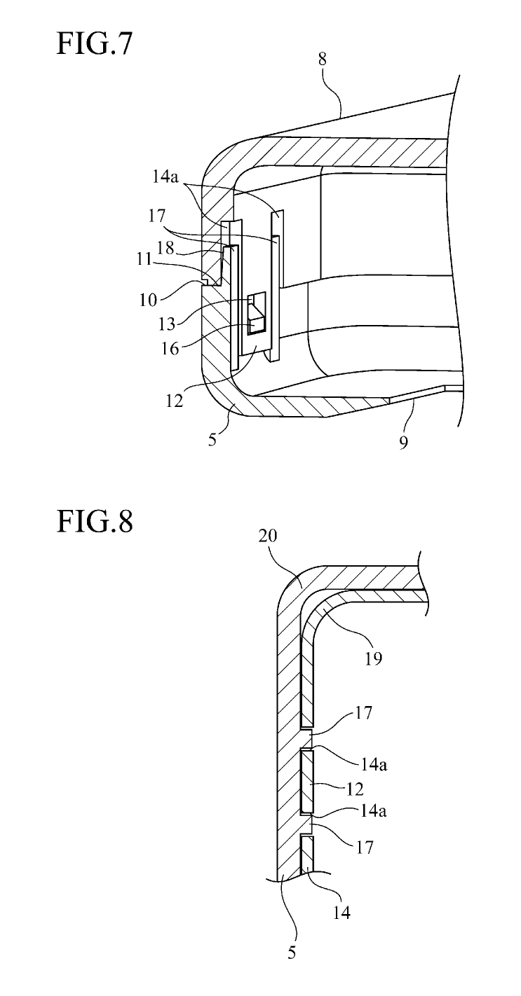

FIG. 5 is an enlarged view of a portion enclosed by a circle shown in FIG. 4. A cross-sectional view taken along the B-B line shown in FIG. 4 is shown in FIG. 6, and a cross-sectional view taken along the C-C line shown in FIG. 4 is shown in FIG. 7. As shown in FIGS. 4 and 6, when the fitting pawls 16 are fitted into the fitting holes 13, respectively, the front panel 5 and the rear panel 8 are held in a state in which the front panel 5 and the rear panel 8 are mounted to each other.

In this state, the rear rib 14 is inserted into the inside of the front panel 5 while the front rib 17 is inserted into the inside of the rear panel 8, and the peripheral portions 10 and 11 are joined to each other. Because the surface of the rear rib 14 being in contact with the front panel 5 is shaped into the tapered surface 15 as shown in FIG. 5, only a base end of the rear rib 14 is in partial contact with the inner surface of the front panel 5. Further, because the surface of each front rib 17 being in contact with the rear panel 8 is shaped into the tapered surface 18 as shown in FIG. 7, only the base end of each front rib 17 is in partial contact with the inner surface of the rear panel 8.

As shown in FIG. 2, the display device 1 using the display device housing 2 is rotatably supported by hinges disposed at both the right and left ends thereof. The user is allowed to hold and rotate the display device housing 2 to adjust the attitude of the display device housing. When the rear panel 8 is bent by an external force exerted thereon at this time, the peripheral portion 11 is forced to be swung open outwardly, but does not move because the rear rib 14 is in partial contact with the inner surface of the front panel 5. Therefore, the joint portions of the peripheral portion 11 and the peripheral portion 10 can be prevented from rubbing against each other, and therefore the occurrence of a squeak noise can be suppressed. Further, because the contact surface portion of the rear rib 14 being in contact with the front panel 5 is only at the base end of the rear rib and has a small area, the occurrence of a squeak noise can be suppressed.

When the front panel 5 is bent by an external force exerted thereon, the peripheral portion 10 is forced to be swung open outwardly, but does not move because each of the front ribs 17 is in partial contact with the inner surface of the rear panel 8. Therefore, the joint portions of the peripheral portion 11 and the peripheral portion 10 can be prevented from rubbing against each other, and therefore the occurrence of a squeak noise can be suppressed, while the engagement between each fitting hole 13 and the corresponding fitting pawl 16 can be prevented from being released. Further, because the contact surface portion of each front rib 17 being in contact with the rear panel 8 is only at the base end of the front rib and has a small area, the occurrence of a squeak noise can be suppressed.

FIG. 8 is a cross-sectional view of the display device housing 2 taken along the D-D line shown in FIG. 4, and shows a state in which a corner 19 of the rear rib 14 and a corner 20 of the front panel 5 are mounted to each other. The corner 19 of the rear rib 14 protruding along a corner where two side surfaces of the rear panel 8 intersect has a larger radius of curvature than that of the corner 20 where two side surfaces of the front panel 5 intersect. A gap is disposed in this way between the corners 19 and 20 where it is difficult to provide a design match between the front panel 5 and the rear panel 8 and which easily slip out of place from each other, thereby preventing the corners 19 and 20 from being in contact with each other. As a result, while the front panel 5 and the rear panel 8 can be surely mounted to each other even if the corners 19 and 20 have variations in their sizes, the corners 19 and 20 can be prevented from rubbing against each other.

As mentioned above, the display device housing 2 in accordance with Embodiment 1 is constructed in such a way as to include a front panel 5 having a front surface in which an opening 9 for screen display is formed, and four side surfaces, a rear panel 8 having a rear surface and four side surfaces, the rear panel being mounted to the front panel 5 in such a way that a peripheral portion 11 of the four side surfaces of the rear panel is joined to a peripheral portion 10 of the four side surfaces of the front panel in a state in which the rear and front panels are facing inwardly opposite to each other, a rear rib 14 protruding from a substantially entire perimeter of the peripheral portion 11 of the rear panel 8, and being inwardly inserted into an inside of the front panel 5, a fitting hole 13 opened in a fitting protruding piece 12 of the rear rib 14, and a fitting pawl 16 formed on the front panel 5 and fitted into the fitting hole 13. Therefore, even if an external force is exerted on the display device housing 2, the peripheral portion 11 of the rear panel 8 is not moved outwardly, and hence the joint portions of the front panel 5 and the rear panel 8 are prevented from rubbing against each other, thereby being able to reduce the occurrence of a squeak noise.

Further, in accordance with Embodiment 1, because the rear rib 14 has a tapered surface 15 facing the inner surface of the front panel 5 and being inclined in such a way that the thickness of the rear rib decreases with distance to a free end of the rear rib, the contact surface portion of the rear rib 14 being in contact with the front panel 5 can be reduced in size to a minimum, and the occurrence of a squeak noise can be suppressed.

Further, the display device housing in accordance with Embodiment 1 is constructed in such a way as to have a pair of notches 14a which are cut away in the rear rib 14 on both sides of a fitting hole 13, and a pair of front ribs 17 protruding from the peripheral portion 10 of the front panel 5 and being inwardly inserted into an inside of the rear panel 8 via the pair of notches 14a. Therefore, even if an external force is exerted on the display device housing 2, the peripheral portion 10 of the front panel 5 is not moved outwardly, and hence the joint portions of the front panel 5 and the rear panel 8 are prevented from rubbing against each other, thereby being able to reduce the occurrence of a squeak noise.

Further, in accordance with Embodiment 1, because apart of the rear rib 14 protruding along a corner 19 where two side surfaces of the rear panel 8 intersect has a larger radius of curvature than that of a corner 20 where two side surfaces of the front panel 5 intersect, the corners 19 and 20 do not rub against each other even if the corners 19 and 20 slip out of place from each other because there is a gap between them, thereby being able to prevent the occurrence of a squeak noise.

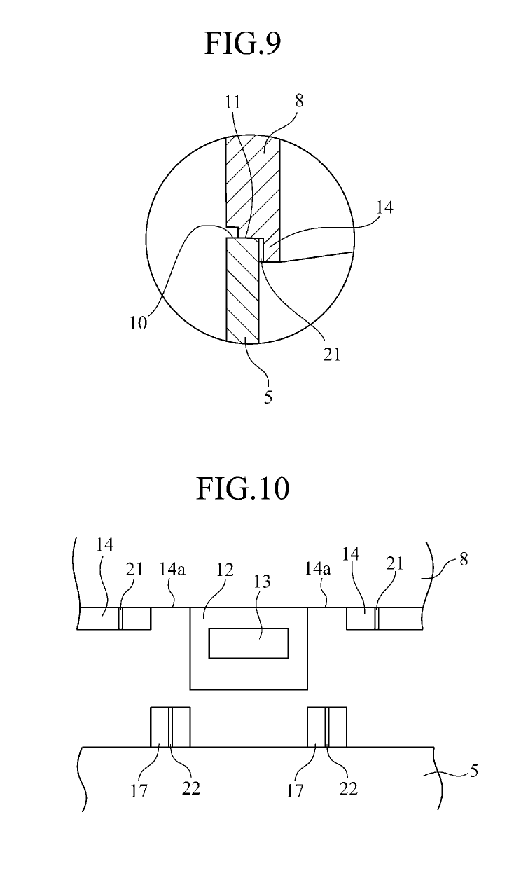

In above-mentioned Embodiment 1, the display device housing is constructed in such a way that the tapered surfaces 15 and 18 are formed on the rear rib 14 and each front rib 17, respectively. As an alternative, contact parts can be disposed instead of the tapered surfaces 15 and 18. An example of the contact parts is shown in FIGS. 9 and 10. FIG. 9 corresponds to a portion enclosed by a circle shown in FIG. 4. FIG. 10 is an enlarged view of each fitting member. The rear rib 14 is constructed in such a way as to be inserted into the inside of the front panel 5 with small gaps being formed between the rear rib and the front panel, and a minute contact part 21 is disposed in such away as to protrude in each of these gaps. The contact part 21 can be disposed on an outer surface of the rear rib 14, as shown in FIGS. 9 and 10, or can be disposed on the inner surface of the front panel 5.

Further, each front rib 17 is constructed in such a way as to be inserted into the inside of the rear panel 8 with small gaps being formed between the front rib and the rear panel, and a contact part 22 is disposed in such a way as to protrude in each of these gaps. This contact part 22 can also be disposed on an outer surface of the front rib 17, as shown in FIG. 10, or can be disposed on the inner surface of the front panel 5 (i.e. on an inner surface of each notch 14a).

Because the contact part 21 being in partial contact with either one of the rear rib 14 and the inner surface of the front panel 5 is disposed on the other one of them, there is provided an advantage of being able to reduce the size of the contact surface portion of the rear rib 14 being in contact with the front panel 5 to a minimum, thereby being able to suppress the occurrence of a squeak noise, like in above-mentioned Embodiment 1. Because the contact part 22 being in partial contact with either one of each front rib 17 and the inner surface of the rear panel 8 is similarly disposed on the other one of them, there is provided an advantage of being able to reduce the size of the contact surface portion of each front rib 17 being in contact with the rear panel 8 to a minimum, thereby being able to suppress the occurrence of a squeak noise.

An arbitrary material, such as a resin, can be used as a material from which the front panel 5 and the rear panel 8 are made . Because a squeak noise occurring when the front panel 5 and the rear panel 8 rub against each other becomes large in a case in which the material used has a large frictional resistance, the advantages provided by the present invention are more effective particularly in such a case.

### INDUSTRIAL APPLICABILITY

As mentioned above, because the display device housing in accordance with the present invention is constructed in such a way that the rear rib protruding from the substantially entire perimeter of the peripheral portion of the rear panel is inwardly inserted into the inside of the front panel, so that the joint portions of the front panel and the rear panel are prevented from rubbing against each other and the occurrence of a squeak noise is reduced, the display device housing is suitable for use as a housing used for a display device or the like, which enables the user to hold the housing to adjust the attitude of the housing.

1. A display device housing inducing
a front panel having a front surface in which an opening for screen display is formed, and four side surfaces,
a rear panel having a rear surface and four side surfaces, said rear panel being mounted to said front panel in such a way that a peripheral portion of the four side surfaces of said rear panel is joined to a peripheral portion of the four side surfaces of said front panel in a state in which said rear and front panels are facing inwardly opposite to each other, a fitting hole opened in a rear rib, and a fitting pawl formed on the front panel and fitted into said fitting hole, wherein said display device housing includes said rear rib protruding from a substantially entire perimeter of the peripheral portion of said rear panel, and being inwardly inserted into an inside of said front panel.

2. (canceled)

3. The display device housing according to claim 1, wherein the rear rib has a tapered surface facing an inner surface of the front panel and being inclined in such a way that its thickness decreases with distance to a free end of the rear rib.

4. The display device housing according to claim 1, wherein a minute contact part being in partial contact with either one of the rear rib and an inner surface of the front panel is disposed on all of four sides of the other one of them.

5. The display device housing according to claim 1, wherein a pair of notches which are cut away in the rear rib on both sides of the fitting hole, and a pair of front ribs protruding from the peripheral portion of the front panel, and being inwardly inserted into an inside of the rear panel via said pair of notches.

6. The display device housing according to claim 5, wherein each of the front ribs has a tapered surface facing an inner surface of the rear panel and being inclined in such a way that its thickness decreases with distance to an end of the front rib.

7. The display device housing according to claim 5, wherein a minute contact part being in partial contact with either one of each of the front ribs and the inner surface of the rear panel is disposed on all of four sides of the other one of them.

8. The display device housing according to claim 1, wherein a part of the rear rib protruding along a corner where two side surfaces of the rear panel intersect has a radius of curvature larger than that of a corner where two side surfaces of the front panel intersect.
